(19) United States
(12) Patent Application Publication
(10) Pub. No.: US 2012/0243319 A1
(43) Pub. Date: Sep. 27, 2012

(54) NONVOLATILE SEMICONDCUTOR MEMORY DEVICE, IC CARD AND PORTABLE APPARATUS

(75) Inventors: Takamichi Kasai, Yokohama-shi (JP); Tomonori Noguchi, Kakamura-shi (JP)

(73) Assignee: KABUSHIKI KAISHA TOSHIBA, Tokyo (JP)

(21) Appl. No.: 13/229,949

(22) Filed: Sep. 12, 2011

(30) Foreign Application Priority Data
Mar. 23, 2011 (JP) 2011-065030

(51) Int. Cl. G11C 16/30

(52) U.S. Cl. 365/185.18

(57) ABSTRACT

According to one embodiment, a nonvolatile semiconductor memory device includes a first nonvolatile memory, and a voltage generation circuit configured to apply a voltage to the first nonvolatile memory, the voltage generation circuit includes a charge pump and an oscillator configured to generate a clock to be used to operate the charge pump. The voltage generation circuit changes a frequency of the clock.

### CROSS-REFERENCE TO RELATED APPLICATIONS

This application is based upon and claims the benefit of priority from prior Japanese Patent Application No. 2011-065030, filed Mar. 23, 2011, the entire contents of which are incorporated herein by reference.

### FIELD

Embodiments described herein relate generally to a nonvolatile semiconductor memory device, an IC (Integrated Circuit) card and a portable apparatus.

### BACKGROUND

There is recently growing the desire to reduce the power consumption of a nonvolatile memory used in a cellular phone or an IC card, and various measures have been taken. The memory is simultaneously required to achieve greater functionality including a larger memory capacity, quick access, and the read-while-write (RWW [enable simultaneous read and write]) function. Hence, implementing lower power consumption is much more difficult.

A NOR flash memory is known as a nonvolatile semiconductor memory used in a cellular phone or an IC card. Channel Hot Electron (CHE) is used to write data in the memory cells of the NOR flash memory. In CHE, a high voltage is applied to a control gate electrode to inject hot electrons into a charge storage layer. On the other hand, FN tunneling is used to erase data from the memory cells of the NOR flash memory. In the FN tunneling, a negative high voltage is applied to the control gate electrode to remove electrons from the charge storage layer.

That is, since the NOR flash memory consumes high power in the write operation and the erase operation, it is difficult to meet the requirement to reduce the power consumption. In addition, when the cellular phone or IC card incorporating the NOR flash memory has a prescribed peak current, it is difficult for the NOR flash memory to satisfy the specifications of the cellular phone or the IC card. Especially when the NOR flash memory has attained the higher functionality including the larger memory capacity, quick access, and the RWW function, the specifications such as the peak current are hard to satisfy.

### BRIEF DESCRIPTION OF THE DRAWINGS

FIG. 1 is a block diagram of a NOR flash memory 10 according to the first embodiment;

FIG. 2 is a circuit diagram of a memory cell array 11;

FIG. 3 is a block diagram of a voltage generation circuit 24;

FIG. 4 is a circuit diagram of a voltage detection circuit 25;

FIGS. 5A and 5B are schematic views for explaining the write and erase operations of a memory cell;

FIG. 6 is a graph for explaining the threshold voltage distribution of memory cells;

FIG. 7 is a timing chart showing the operation of the voltage detection circuit 25;

FIG. 8 is a state transition diagram of a state machine 23 in the rewrite operation;

FIG. 9 is a state transition diagram of the state machine 23 in the rewrite operation;

FIG. 10 is a block diagram of a NOR flash memory 10 according to the second embodiment;

FIG. 11 is a timing chart showing the operation of the NOR flash memory 10;

FIG. 12 is a schematic view of a cellular phone 100 and a SIM card 110; and

FIG. 13 is a block diagram of the SIM card 110.

### DETAILED DESCRIPTION

In general, according to one embodiment, there is provided a nonvolatile semiconductor memory device comprising:

a first nonvolatile memory; and

a voltage generation circuit configured to apply a voltage to the first nonvolatile memory, the voltage generation circuit comprising a charge pump and an oscillator configured to generate a clock to be used to operate the charge pump,

wherein the voltage generation circuit changes a frequency of the clock.

The embodiments will be described hereinafter with reference to the accompanying drawings. In the description which follows, the same or functionally equivalent elements are denoted by the same reference numerals, to thereby simplify the description.

### First Embodiment

### [1. Arrangement of Nonvolatile Semiconductor Memory Device]

A NOR flash memory will be described below as an example of a nonvolatile semiconductor memory device. FIG. 1 is a block diagram of a NOR flash memory 10 according to the first embodiment.

A memory cell array 11 comprises a plurality of NOR flash memory cells arranged in a matrix. Each memory cell is connected to a bit line, a word line, and a source line.

A row decoder 12 is connected to the word lines to select a word line based on a row address. The row decoder 12 applies a predetermined voltage to a word line in the erase operation, the write operation, and the read operation.

A column decoder 13 generates a column select signal to select a bit line based on a column address. The column select signal is sent to a column selector 14. The column selector 14 selects a bit line based on the column select signal and connects it to a sense amplifier (S/A) 15 or a write/erase circuit 16. The sense amplifier 15 detects and amplifies data read from a memory cell selected by the row decoder 12 and the column decoder 13.

The write/erase circuit 16 writes data in a predetermined memory cell unit (page) at once. The write/erase circuit 16 also erases data in a predetermined memory cell unit (block) at once. In the write operation and the erase operation, the write/erase circuit 16 controls the voltages of a bit line, a word line, a source line, and a well where a memory cell is formed.

A data latch 17 externally receives write data and holds it. The write data held by the data latch 17 is sent to the write/erase circuit 16 and a verification circuit 18.

In the write operation, the verification circuit 18 performs a verification operation using the write data sent from the data latch 17 and data read by the sense amplifier 15. In the erase operation, the verification circuit 18 verifies whether the data read by the sense amplifier 15 indicates the erase state. The verification result of the verification circuit 18 is sent to a state machine 23.

An output buffer 19 externally receives an output enable signal OE. When the output enable signal OE is asserted (for example, high), the output buffer 19 externally outputs the read data sent from the sense amplifier 15. A command decoder 20 externally receives a chip enable signal CE and a write enable signal WE. When both the chip enable signal CE and the write enable signal WE are asserted (for example, high), the command decoder 20 receives an externally input command. The command decoder 20 interprets the command and sends a command signal to the state machine 23.

An address latch 21 externally receives an address and holds it. An address decoder 22 externally receives the chip enable signal CE and also receives the address from the address latch 21. When the chip enable signal CE is asserted, the address decoder 22 decodes the address to send a row address to the row decoder 12 and a column address to the column decoder 13.

A voltage generation circuit 24 generates various kinds of voltages necessary for the erase operation, the write operation, and the read operation using a power supply voltage VDD and a ground voltage VSS, which are externally supplied. A voltage detection circuit 25 externally receives the power supply voltage VDD and detects whether it is lower than a predetermined level. The detailed arrangements of the voltage generation circuit 24 and the voltage detection circuit 25 will be described later.

The state machine 23 controls the modules in the NOR flash memory 10. The state machine 23 controls the states of the modules in the NOR flash memory 10, thereby controlling the erase operation, the write operation, and the read operation. In this specification, the erase operation and the write operation will collectively be expressed as a rewrite operation. Note that although the state machine 23 sends control signals to the sense amplifier 15, the verification circuit 18 and so on as well, the control signal lines are not illustrated to avoid complicatedness in the diagram.

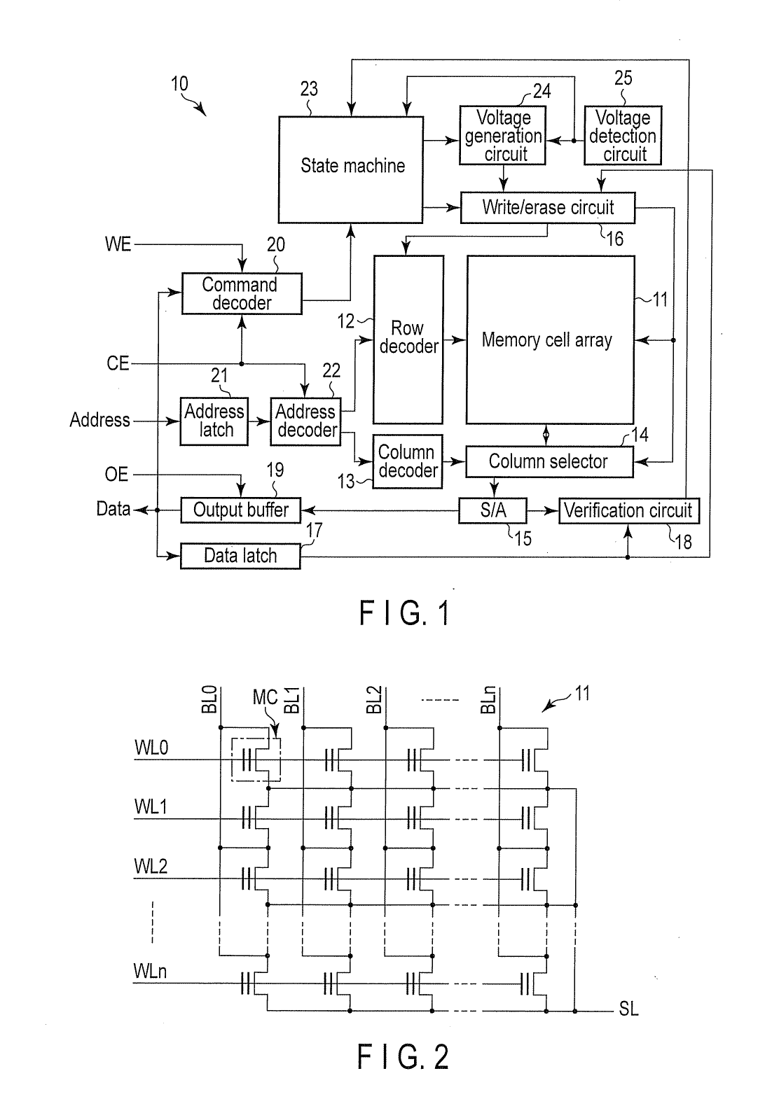

The arrangement of the memory cell array 11 will be explained next. FIG. 2 is a circuit diagram of the memory cell array 11. The memory cell array 11 comprises ((m+1)×(n+1)) (m, n: integer of 1 or more) memory cells MC. An n-well is formed in a p-semiconductor substrate. A p-well is formed in the n-well. The memory cell MC is formed in the p-well. The memory cell MC is a MOSFET comprising source and drain regions provided in the p-well apart from each other, and a stacked gate including a charge storage layer (for example, a floating gate electrode) provided on a tunnel insulating film on the p-well between the source region and the drain region and a control gate electrode provided on an intergate insulating film formed on the floating gate electrode. Each of the source and drain regions is formed from an n⁺-diffusion region formed by heavily doping the p-well with an n-impurity.

The control gate electrodes of the memory cells MC on the same row are commonly connected to one of word lines WL0 to WLm. The drains of the memory cells MC on the same column are commonly connected to one of bit lines BL0 to BLn. The sources of the memory cells MC are commonly connected to a single source line SL. A set of (n+1) memory cells MC connected to the same word line is called a page. Note that the page need only be a set of a plurality of memory cells connected to the same word line. In this embodiment, a set of (n+1) memory cells is defined as a page for the descriptive convenience. The page is the minimum data write unit. A plurality of pages form a unit called a block. The block is formed from a plurality of memory cells that share a well and serves as the minimum data erase unit.

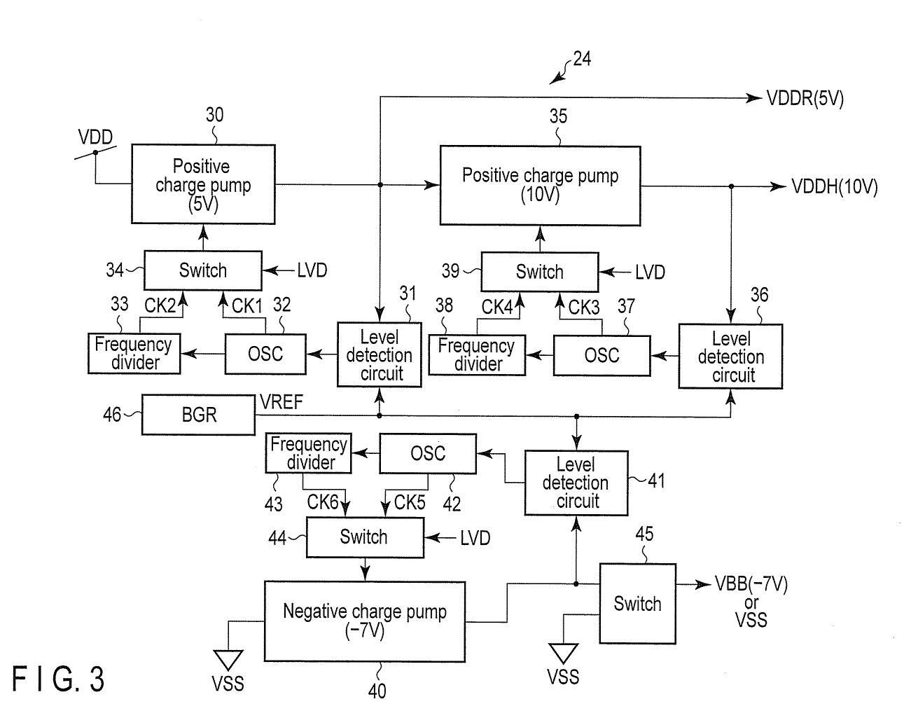

The arrangement of the voltage generation circuit 24 will be described next. FIG. 3 is a block diagram of the voltage generation circuit 24.

A reference voltage generation circuit 46 generates a reference voltage VREF. The reference voltage VREF is supplied to three level detection circuits 31, 36, and 41. As the reference voltage generation circuit 46, for example, a band-gap reference (BGR) circuit is used. The BGR circuit generates the reference voltage using the band gap voltage of a semiconductor and has an excellent temperature-to-voltage characteristic. For this reason, the BGR circuit can generate the reference voltage VREF with a small voltage variation.

A positive charge pump 30 serving as a step-up circuit raises the externally supplied power supply voltage VDD to generate a voltage VDDR (for example, 5 V). The charge pump is formed by connecting a plurality of capacitors in parallel via diodes, and generates a predetermined voltage by sequentially transferring the charges of the capacitors in accordance with normal and inverted clocks. The level detection circuit 31 detects the output level of the positive charge pump 30 and controls the operation (on/off) of an oscillator (OSC) 32. The oscillator 32 generates a clock CK1 having a predetermined frequency. Clock CK1 from the oscillator 32 is sent to a switch 34 and a frequency divider 33.

The frequency divider 33 frequency-divides clock CK1 to generate a clock CK2 having a frequency lower than that of clock CK1. Clock CK2 from the frequency divider 33 is sent to the switch 34. The switch 34 selects one of clocks CK1 and CK2 based on a low voltage detection signal LVD sent from the voltage detection circuit 25.

A positive charge pump 35 serving as a step-up circuit raises the voltage VDDR supplied from the positive charge pump 30 to generate a voltage VDDH (for example, 10 V). The level detection circuit 36 detects the output level of the positive charge pump 35 and controls the operation (on/off) of an oscillator (OSC) 37. The oscillator 37 generates a clock CK3 having a predetermined frequency. Clock CK3 from the oscillator 37 is sent to a switch 39 and a frequency divider 38.

The frequency divider 38 frequency-divides clock CK3 to generate a clock CK4 having a frequency lower than that of clock CK3. Clock CK4 from the frequency divider 38 is sent to the switch 39. The switch 39 selects one of clocks CK3 and CK4 based on the low voltage detection signal LVD sent from the voltage detection circuit 25.

A negative charge pump 40 serving as a step-down circuit lowers the externally supplied ground voltage VSS to generate a voltage VBB (for example, −7 V). The level detection circuit 41 detects the output level of the negative charge pump 40 and controls the operation (on/off) of an oscillator (OSC) 42. The oscillator 42 generates a clock CK5 having a predetermined frequency. Clock CK5 from the oscillator 42 is sent to a switch 44 and a frequency divider 43.

The frequency divider 43 frequency-divides clock CK5 to generate a clock CK6 having a frequency lower than that of clock CK5. Clock CK6 from the frequency divider 43 is sent to the switch 44. The switch 44 selects one of clocks CK5 and CK6 based on the low voltage detection signal LVD sent from the voltage detection circuit 25.

A switch 45 selects one of the voltage VBB (−7 V) and the ground voltage VSS (0 V). That is, the switch 45 outputs 0 V in the write operation and −7 V in the erase operation. The select operation of the switch 45 is controlled by the state machine 23.

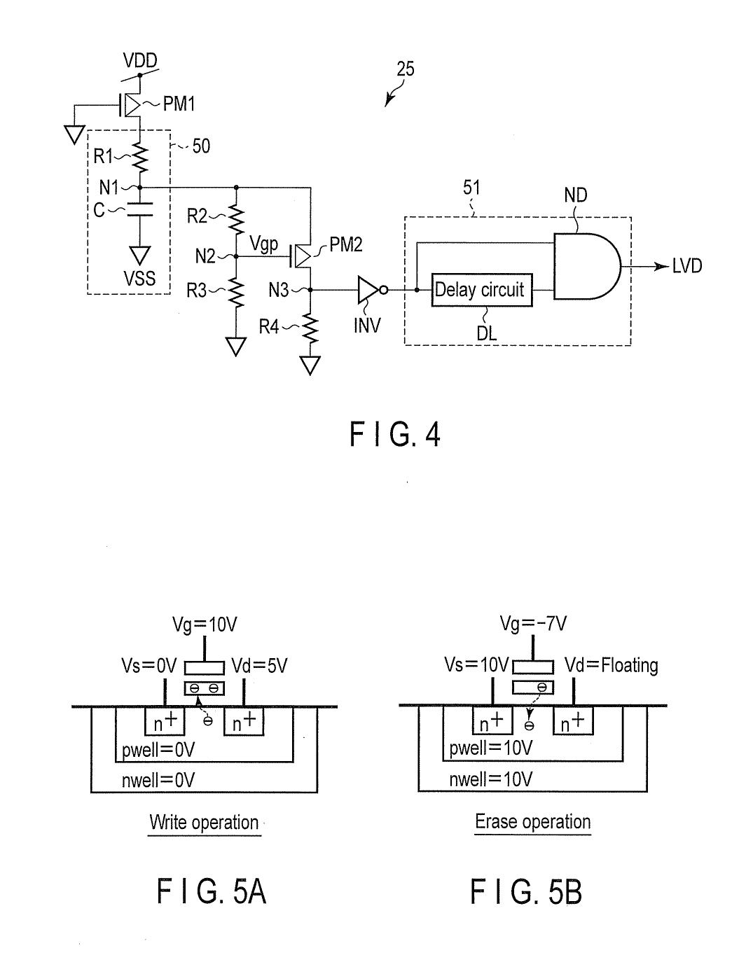

The arrangement of the voltage detection circuit 25 will be described next. FIG. 4 is a circuit diagram of the voltage detection circuit 25.

A p-channel MOSFET PM1 functions as a buffer. The source of the p-channel MOSFET PM1 is connected to a power supply terminal to which the power supply voltage VDD is applied externally. The gate of the p-channel MOSFET PM1 is grounded, and the drain is connected to a low-pass filter 50.

The low-pass filter 50 removes a steep power supply transition or noise. The low-pass filter 50 includes a resistor R1 and a capacitor C. One terminal of resistor R1 is connected to the drain of the p-channel MOSFET PM1. The other terminal of resistor R1 is connected to the first electrode of the capacitor C via a connection node N1. The second electrode of the capacitor C is grounded.

Resistors R2 and R3 are connected in series between connection node N1 and the ground terminal VSS. Resistors R2 and R3 divide the voltage of connection node N1. The source of a p-channel MOSFET PM2 is connected to connection node N1, the gate is connected to a connection node N2 between resistors R2 and R3, and the drain is connected to one terminal of a resistor R4 via a connection node N3. The other terminal of resistor R4 is grounded.

The input terminal of an inverter circuit INV is connected to connection node N3, and the output terminal is connected to a noise canceller 51. The noise canceller 51 removes a steep power supply transition or noise. The noise canceller 51 includes a delay circuit DL and a NAND gate ND. The output terminal of the inverter circuit INV is connected to the first input terminal of the NAND gate ND and the input terminal of the delay circuit DL. The output terminal of the delay circuit DL is connected to the second input terminal of the NAND gate ND. The NAND gate ND outputs the low voltage detection signal LVD. The function of the noise canceller 51 can prevent the low voltage detection signal LVD from frequently changing due to, for example, noise in the power supply voltage VDD.

### [2. Operation]

The operation of the NOR flash memory 10 having the above-described arrangement will be explained.

The write operation will be described first. Upon externally receiving a write command, the state machine 23 executes the write operation.

If the level of the power supply voltage VDD is normal, the low voltage detection signal LVD is negated (low). In this case, the switches 34, 39, and 44 of the voltage generation circuit 24 select the clocks from the oscillators 32, 37, and 42, respectively. The state machine 23 starts the positive charge pumps 30 and 35 to generate the voltage VDDR (5 V) and the voltage VDDH (10 V).

The write/erase circuit 16 applies 10 V to a word line WL selected by a row address and then 5 V to a bit line BL selected by a column address. The write/erase circuit 16 also applies 0 V to the source line SL and 0 V to the n-well and the p-well in which the selected memory cell is formed.

FIG. 5A is a schematic view for explaining the write operation of the memory cell. The write operation of the memory cell is performed by Channel Hot Electron (CHE). The write/erase circuit 16 performs voltage control to set a gate voltage Vg=10 V, a source voltage Vs=0 V, and a drain voltage Vd=5 V in the selected memory cell. Hot electrons generated near the drain are thus injected into the floating gate electrode. In this case, a cell threshold voltage Vth rises due to the electrons injected into the floating gate electrode, and an off state (write state) is obtained at the read potential (for example, 5 V). This write state is defined as “0” data. When the write has ended, the write/erase circuit 16 sets the bit line to 0 V and discharges the word line to 5 V.

The erase operation will be described next. Upon externally receiving an erase command, the state machine 23 executes the erase operation.

The state machine 23 starts the positive charge pumps 30 and 35 and the negative charge pump 40 to generate the voltage VDDH (10 V) and the voltage VBB (−7 V). The write/erase circuit 16 applies −7 V to the word line WL in the selected block of the erase target, and sets the bit line BL in the floating state. The write/erase circuit 16 also applies 10 V to the source line SL and 0 V to the n-well and the p-well in which the selected block is formed.

FIG. 5B is a schematic view for explaining the erase operation of the memory cell. The erase operation of the memory cell is performed by FN tunneling. The write/erase circuit 16 performs voltage control to set the gate voltage Vg=−7 V and the source voltage Vs=10 V and sets the drain in the floating state. A high electric field of 17 V is applied to the tunnel insulating film so that the electrons are removed from the floating gate electrode due to the FN tunneling phenomenon. In this case, the cell threshold voltage Vth lowers because of few electrons in the floating gate electrode, and an on state (erase state) is obtained at the read potential (for example, 5 V). This erase state is defined as “1” data.

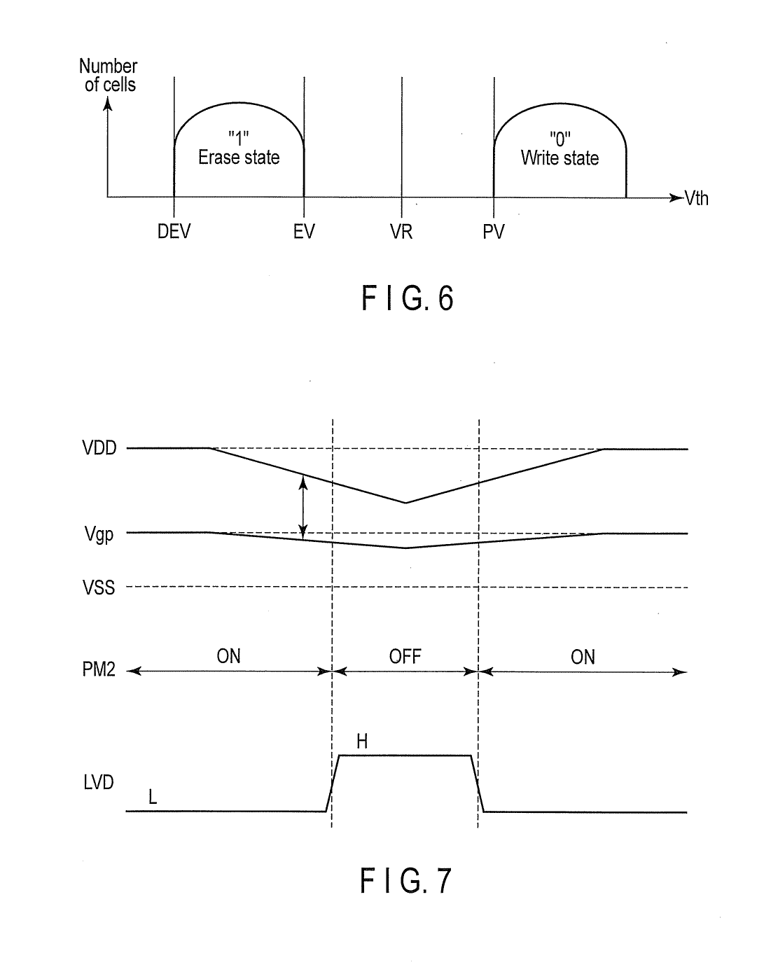

FIG. 6 is a graph for explaining the threshold voltage distribution of memory cells. For a memory cell in the erase state, its threshold voltage is set within a predetermined voltage distribution by repeating the erase operation and the write operation. Similarly, for a memory cell in the write state, its threshold voltage is set within a predetermined voltage distribution by repeating the write operation and the verification operation.

The threshold voltage of the memory cell in the erase state is set between an overerase verification voltage OEV and an erase verification voltage EV. The threshold voltage of the memory cell in the write state is set to be greater than or equal to a write verification voltage PV. When a read voltage VR between the erase verification voltage EV and the write verification voltage PV is applied to the word line, the memory cell in the erase state is in the on state. On the other hand, the memory cell in the write state is in the off state. Hence, the data of the memory cells can be discriminated. The overerase verification voltage OEV, the erase verification voltage EV, the read voltage VR, and the write verification voltage PV hold a relationship “OEV<EV<VR<PV”.

The read operation will be described next. Upon externally receiving a read command, the state machine 23 executes the read operation.

The sense amplifier 15 charges the bit line BL selected by a column address to, for example, 1 V. The source line SL is applied with 0 V. Then, the row decoder 12 applies, for example, 5 V to the word line WL selected by a row address. In this case, a current flows to the memory cell in the erase state, and no current flows to the memory cell in the write, state. The sense amplifier 15 detects and amplifies the current, thereby reading “0” data or “1” data.

The operation of the voltage detection circuit 25 will be described next. FIG. 7 is a timing chart showing the operation of the voltage detection circuit 25.

Referring to FIG. 4, when the power supply voltage VDD satisfies the following condition, the voltage detection circuit 25 operates to assert the low voltage detection signal LVD (high).

VDD·{R2/(R2+R3)}<|Vthp|

where Vthp is the threshold voltage of the p-channel MOSFET PM2, which is a negative voltage. |Vthp| is the absolute value notation. “VDD·{R2/(R2+R3)}” is the voltage drop across resistor R2, that is, the gate-source voltage of the p-channel MOSFET PM2. A gate voltage Vgp of the p-channel MOSFET PM2 is given by “VDD·{R3/(R2+R3)}”. The power supply voltage VDD is divided by resistors R2 and R3. The values of resistors R2 and R3 are set such that the p-channel MOSFET PM2 is turned on when the power supply voltage VDD is the normal prescribed voltage. Hence, when the power supply voltage VDD is the normal prescribed voltage, the p-channel MOSFET PM2 is on. The output of the inverter circuit INV thus goes low, and the voltage detection circuit 25 negates the low voltage detection signal LVD (low).

The low voltage detection signal LVD is supplied to the switches 34, 39, and 44 of the voltage generation circuit 24. When the low voltage detection signal LVD goes low, the switches 34, 39, and 44 select clocks CK1, CK3, and CK5 from the oscillators 32, 37, and 42, respectively. Since the frequencies of the clocks supplied to the charge pumps 30, 35, and 40 are normal, they perform the voltage generation operation at the normal speed.

Subsequently, as shown in FIG. 7, as the power supply voltage VDD drops, that is, the drop of the power supply voltage VDD becomes large, the gate voltage Vgp also lowers. When the gate-source voltage “VDD·{R2/(R2+R3)}” of the p-channel MOSFET PM2 becomes lower than the threshold |Vthp|, the p-channel MOSFET PM2 is turned off. The output of the inverter circuit INV thus goes high, and the voltage detection circuit 25 asserts the low voltage detection signal LVD (high).

When the low voltage detection signal LVD goes high, the switches 34, 39, and 44 select clocks CK2, CK4, and CK6 from the frequency dividers 33, 38, and 43, respectively. Since the frequencies of the clocks supplied to the charge pumps 30, 35, and 40 lower, their current consumption decreases. This allows to suppress the current consumption of the voltage generation circuit 24, which in turn suppresses that of the NOR flash memory 10.

Next, as shown in FIG. 7, as the power supply voltage VDD that has largely dropped rises, the gate voltage Vgp also rises. When the gate-source voltage “VDD·{R2/(R2+R3)}” of the p-channel MOSFET PM2 becomes greater than or equal to the threshold |Vthp|, the p-channel MOSFET PM2 is turned on. The output of the inverter circuit INV thus goes low, and the voltage detection circuit 25 makes the low voltage detection signal LVD low.

When the low voltage detection signal LVD goes low, the switches 34, 39, and 44 select clocks CK1, CK3, and CK5 from the oscillators 32, 37, and 42, respectively. Since the frequencies of the clocks supplied to the charge pumps 30, 35, and 40 are normal, they perform the voltage generation operation at the normal speed.

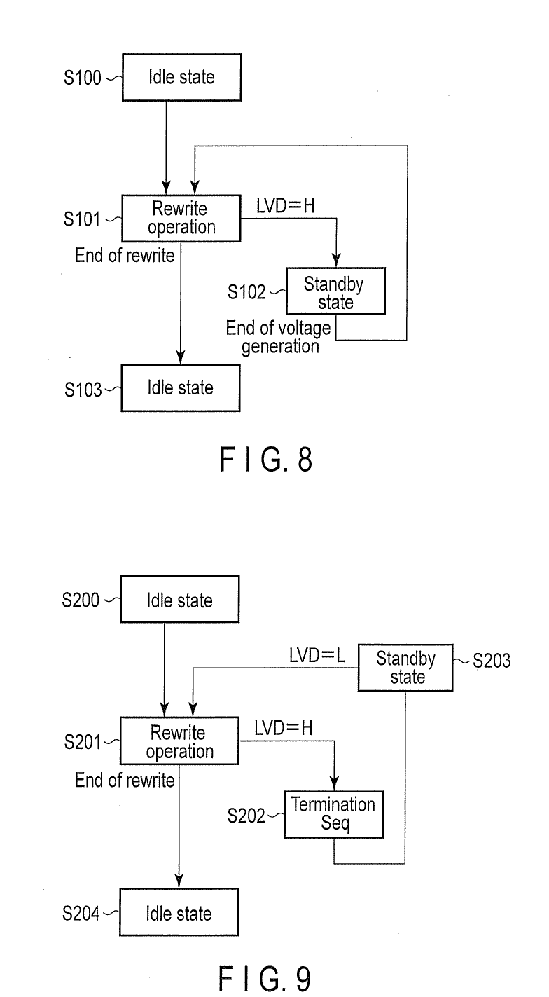

Note that when the frequencies of the clocks supplied to the charge pumps 30, 35, and 40 lower, their charge time increases. For this reason, in the rewrite operation, the state machine 23 prolongs the state transition time by the same amount as the increase in the charge time of the charge pumps 30, 35, and 40, thereby adjusting to normally perform the rewrite operation. FIG. 8 is a state transition diagram of the state machine 23 in the rewrite operation.

Upon externally receiving an erase command or a write command, the state machine 23 exits the idle state (step S100) and executes the rewrite operation (step S101). During the rewrite operation, the state machine 23 monitors the low voltage detection signal LVD sent from the voltage detection circuit 25.

When the low voltage detection signal LVD goes high, the state machine 23 transits to a standby state (step S102). In this standby state, the state machine 23 monitors the outputs of the level detection circuits 31, 36, and 41 of the voltage generation circuit 24, and waits until out of the voltages VDDR, VDDH, and VBB, voltages necessary for the current rewrite operation reach prescribed levels.

Upon detecting generation of the voltages necessary for the current rewrite operation, the state machine 23 returns to the rewrite operation. When the rewrite operation is completed, the state machine 23 transits to the idle state (step S103).

### [3. Modification]

When the voltage detection circuit 25 detects that a voltage drop greater than or equal to a prescribed value has occurred in the power supply voltage VDD (when the low voltage detection signal LVD is asserted), the state machine 23 stops the rewrite operation. After the low voltage detection signal LVD has returned to the normal prescribed voltage (when the low voltage detection signal LVD is negated), the rewrite operation may be resumed newly.

FIG. 9 is a state transition diagram of the state machine 23 in the rewrite operation according to the modification. Upon externally receiving an erase command or a write command, the state machine 23 exits the idle state (step S200) and executes the rewrite operation (step S201). During the rewrite operation, the state machine 23 monitors the low voltage detection signal LVD sent from the voltage detection circuit 25.

When the low voltage detection signal LVD goes high, the state machine 23 executes the termination sequence (termination Seq) (step S202). The termination sequence is processing of resetting the rewrite operation of the NOR flash memory 10. Various kinds of voltages are also reset.

Subsequently, the state machine 23 transits to the standby state (step S203). In this standby state, the state machine 23 monitors the low voltage detection signal LVD sent from the voltage detection circuit 25. When the low voltage detection signal LVD goes low, the state machine 23 newly resumes the rewrite operation, that is, executes the rewrite operation again from the beginning (step S201). When the rewrite operation is completed, the state machine 23 transits to the idle state (step S204).

### [4. Effects]

As described above in detail, in the first embodiment, the NOR flash memory 10 comprises the voltage generation circuit 24 that generates various kinds of voltages necessary for the rewrite operation (the erase operation and the write operation) of the memory cell array 11, and the voltage detection circuit 25 that monitors the external power supply voltage VDD and detects that it has fallen below a predetermined level. The voltage generation circuit 24 comprises the charge pump 30 and the oscillator 32 that generates a clock to operate the charge pump 30. When the power supply voltage VDD has fallen below the predetermined level, the voltage generation circuit 24 lowers the frequency of the clock to be used to operate the charge pump 30.

Hence, according to the first embodiment, when the power supply voltage VDD has dropped, the current consumption of the voltage generation circuit 24 can be suppressed, which, in turn, suppresses that of the NOR flash memory 10. This allows to reduce the peak (peak current) of the current consumption of the NOR flash memory 10. Even when the NOR flash memory 10 of this embodiment is mounted on a chip with strict specifications concerning the peak current, the NOR flash memory 10 that satisfies the specifications can be implemented.

When the voltage detection circuit 25 detects that a voltage drop greater than or equal to a prescribed value has occurred in the power supply voltage VDD, the state machine 23 delays the state transition of the rewrite operation by the same amount as the increase in the charge time of the charge pumps. This enables to normally complete the rewrite operation even when a voltage drop greater than or equal to a prescribed value has occurred in the power supply voltage VDD.

In addition, when the voltage detection circuit 25 detects that a voltage drop greater than or equal to a prescribed value has occurred in the power supply voltage VDD, the state machine 23 stops the rewrite operation. After the power supply voltage VDD has returned to the normal prescribed voltage, the rewrite operation is newly resumed. This enables to normally complete the rewrite operation even when a voltage drop greater than or equal to a prescribed value has occurred in the power supply voltage VDD.

### Second Embodiment

In the second embodiment, an application example of a NOR flash memory having the read-while-write (RWW) function of enabling to execute read and write (rewrite) at the same time will be described. That is, the NOR flash memory of the second embodiment has functions of managing the memory cell array divisionally as a plurality of banks and performing the rewrite operation in the first bank and simultaneously performing the read operation in the second bank.

### 1. Arrangement of Nonvolatile Semiconductor Memory Device]

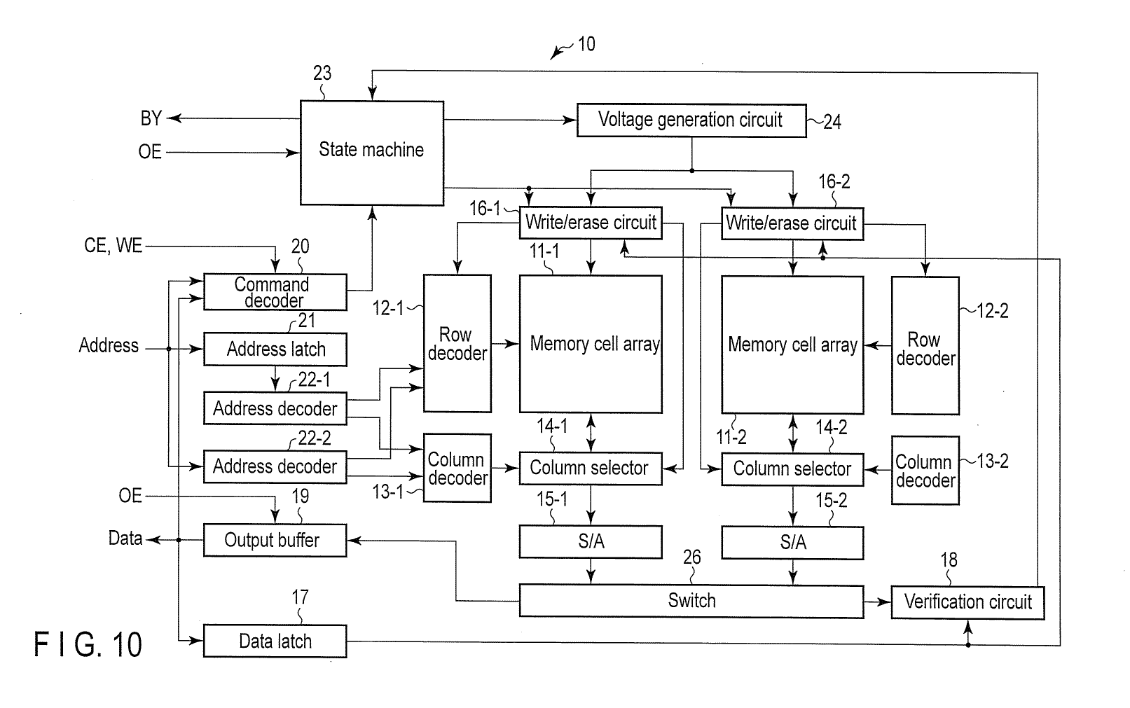

FIG. 10 is a block diagram of a NOR flash memory 10 according to the second embodiment. The NOR flash memory 10 comprises a plurality of memory cell arrays (banks) 11. In this embodiment, an example will be described in which the NOR flash memory 10 comprises two memory cell arrays 11-1 and 11-2.

The NOR flash memory 10 comprises two row decoders 12-1 and 12-2, two column decoders 13-1 and 13-2, two column selectors 14-1 and 14-2, two sense amplifiers (S/A) 15-1 and 15-2, and two write/erase circuits 16-1 and 16-2 corresponding to the two memory cell arrays 11-1 and 11-2, respectively. A switch 26 selects one of the outputs of the sense amplifiers 15-1 and 15-2 under the control of a state machine 23.

An address decoder 22-1 is an address decoder for write/erase. Address decoder 22-1 receives an address from an address latch 21, sends a row address to row decoders 12-1 and 12-2, and sends a column address to column decoders 13-1 and 13-2. An address decoder 22-2 is an address decoder for read. Address decoder 22-2 externally receives an address, sends a row address to row decoders 12-1 and 12-2, and sends a column address to column decoders 13-1 and 13-2. Note that the signal lines from address decoders 22-1 and 22-2 to row decoder 12-2 and column decoder 13-2 are not illustrated in FIG. 10 to avoid complicatedness in the diagram.

A command decoder 20 externally receives a chip enable signal CE and a write enable signal WE. When both the chip enable signal CE and the write enable signal WE are asserted (for example, high), the command decoder 20 receives externally input command and address. This address enables to discriminate the memory cell array as the target of the erase operation, the write operation, and the read operation. The command decoder 20 interprets the command and sends a command signal to the state machine 23.

In this embodiment, the voltage detection circuit 25 described in the first embodiment is unnecessary. A frequency switching signal FSS generated by the state machine 23 replaces the low voltage detection signal LVD generated by the voltage detection circuit 25. The arrangement of a voltage generation circuit 24 is the same as in FIG. 3 except that the frequency switching signal FSS sent from the state machine 23 replaces the low voltage detection signal LVD sent from the voltage detection circuit 25. The remaining modules in the NOR flash memory 10 have the same arrangement as in the first embodiment.

### [2. Operation]

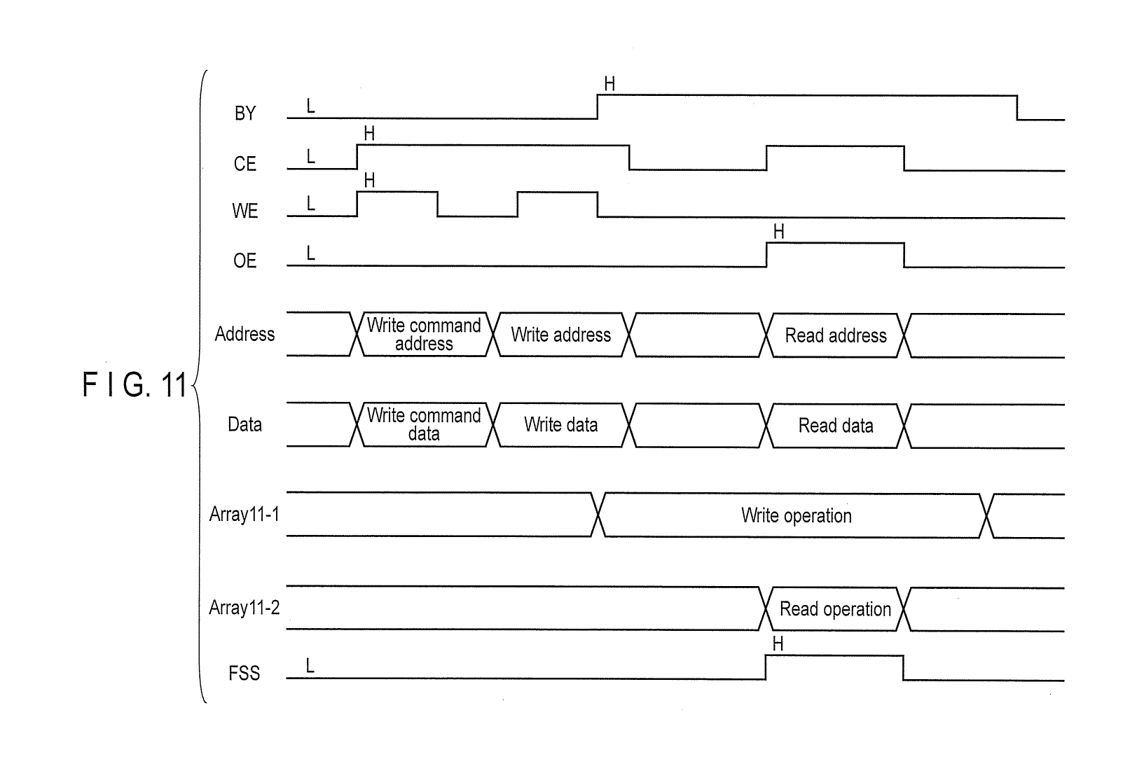

The operation of the NOR flash memory 10 will be explained next. FIG. 11 is a timing chart showing the operation of the NOR flash memory 10 having the RWW function.

The chip enable signal CE and the write enable signal WE are asserted to externally input a write command (for example, including a write command address and write command data) and write data to the NOR flash memory 10. The write command is identified based on the combination of the write command address and the write command data arbitrarily determined in advance. The command decoder 20 interprets the write command and sends a command signal to the state machine 23. The write address is held by the address latch 21. The write data is held by a data latch 17. Address decoder 22-1 decodes the write address held by the address latch 21, sends a row address to one of row decoders 12-1 and 12-2, and sends a column address to one of column decoders 13-1 and 13-2.

Next, the state machine 23 asserts a busy signal BY (high) and executes a series of write operations in, for example, the memory cell array 11-1. At this time, the state machine 23 negates the frequency switching signal FSS (low). In this case, switches 34, 39, and 44 of the voltage generation circuit 24 select clocks from oscillators 32, 37, and 42, respectively, as in the first embodiment. Hence, charge pumps 30, 35, and 40 operate using clocks CK1, CK3, and CK5.

Subsequently, the chip enable signal CE and an output enable signal OE are asserted to externally input a read address to the NOR flash memory 10. In this embodiment, the output enable signal OE is used as a trigger signal to start the read operation. Address decoder 22-2 decodes the read address, sends a row address to one of row decoders 12-1 and 12-2, and sends a column address to one of column decoders 13-1 and 13-2.

Next, the state machine 23 executes a series of read operations in, for example, the memory cell array 11-2. That is, the state machine 23 executes the write operation and the read operation simultaneously and asynchronously. Since the current operation is the RWW operation, the state machine 23 asserts the frequency switching signal FSS (high).

When the frequency switching signal FSS goes high, the switches 34, 39, and 44 of the voltage generation circuit 24 select clocks CK2, CK4, and CK6 from frequency dividers 33, 38, and 43, respectively, as in the first embodiment. Since the frequencies of the clocks supplied to the charge pumps 30, 35, and 40 lower, the current consumption of the charge pumps 30, 35, and 40 decreases. This allows to suppress the current consumption of the voltage generation circuit 24, which in turn suppresses that of the NOR flash memory 10.

When the read operation has ended, the state machine 23 makes the frequency switching signal FSS low. When the frequency switching signal FSS goes low, the switches 34, 39, and 44 select clocks CK1, CK3, and CK5 from the oscillators 32, 37, and 42, respectively. Since the frequencies of the clocks supplied to the charge pumps 30, 35, and 40 are normal, they perform the voltage generation operation at the normal speed.

Note that when the frequencies of the clocks supplied to the charge pumps 30, 35, and 40 lower, their charge time increases. For this reason, in the write operation, the state machine 23 prolongs the state transition time by the same amount as the increase in the charge time of the charge pumps 30, 35, and 40, thereby adjusting to normally perform the rewrite operation.

### [3. Effects]

As described above in detail, in the second embodiment, the NOR flash memory 10 has the RWW function capable of simultaneously executing the write operation and the read operation. Upon receiving a read command (in this embodiment, asserting the output enable signal OE) for the second band during execution of the write operation in the first bank, the frequency of the clock to be used to operate the charge pump 30 of the voltage generation circuit 24 is lowered.

Hence, according to the second embodiment, the current consumption of the voltage generation circuit 24 can be suppressed, which, in turn, suppresses that of the NOR flash memory 10 during the RWW operation. This allows to reduce the peak current of the NOR flash memory 10. Even when the NOR flash memory 10 of this embodiment is mounted on a chip with strict specifications concerning the peak current, the NOR flash memory 10 that satisfies the specifications can be implemented.

Note that in this embodiment, the erase operation and the read operation can also be executed simultaneously like the write operation. In other words, this embodiment is also applicable to simultaneously executing the rewrite operation and the read operation.

### Third Embodiment

In the third embodiment, an arrangement example will be described in which the NOR flash memory 10 of the first or second embodiment is applied to an IC card (smart card).

An IC card includes an IC memory (EPROM or EEPROM) and a microcomputer both embedded in a card. Some IC cards have strict specifications of current consumption, the peak current, and the like. Hence, the NOR flash memory 10 described in the first or second embodiment, which can reduce current consumption and the peak current is suitable for the IC card.

In this embodiment, a Subscriber Identity Module (SIM) card will be exemplified as a kind of IC card. The SIM card is a detachable IC card used in a cellular phone (portable apparatus) and records a unique ID number and telephone number to identify the cellular phone subscriber.

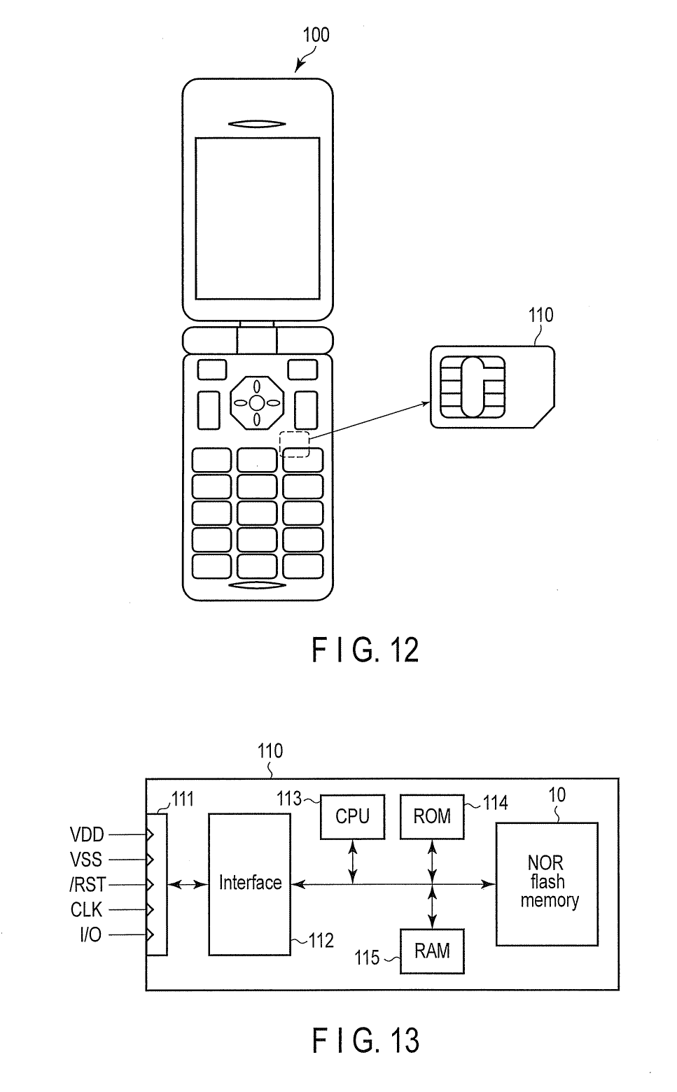

FIG. 12 is a schematic view of a cellular phone 100 and a SIM card 110. The cellular phone 100 has a slot to receive the SIM card 110. The SIM card 110 is inserted into the cellular phone 100 from this slot. The SIM card 110 inserted in the cellular phone 100 is electrically connected to the cellular phone 100 via a terminal group.

FIG. 13 is a block diagram of the SIM card 110. The SIM card 110 comprises a terminal group 111, an interface 112, a CPU 113, a ROM 114, a RAM 115, and the NOR flash memory 10 described in the first or second embodiment.

The terminal group 111 comprises a power supply terminal VDD, a ground terminal VSS, a reset terminal /RST, a clock terminal CLK, and an input/output terminal I/O. The interface 112 performs interface processing of signals and data input from the terminal group 111. The interface 112 also performs interface processing when outputting data to the cellular phone 100.

The ROM 114 stores firmware and the like as permanent information at the time of manufacture of the SIM card 110. The RAM 115 serves as the work area of the CPU 113 and thus serves as a memory to read or write temporary data. The CPU 113 generally controls the modules in the SIM card 110.

When the SIM card 110 incorporates the NOR flash memory 10 described in the first or second embodiment, the current consumption or peak current of the SIM card 110 can be reduced. This makes it possible to implement the SIM card 110 that satisfies the specifications concerning the current consumption or peak current.

Note that the method of reducing the peak current in the write and erase operations has been described in the above embodiments. However, the embodiments may be applied to the read operation if the peak current increases in the read operation.

Although the NOR flash memory has been exemplified as the nonvolatile semiconductor memory device in the above embodiments, they may be applied to even a NAND flash memory. In addition, the embodiments are applicable not only to a flash memory but also to an EEPROM or a nonvolatile semiconductor memory device of another storage scheme other than the flash memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a first nonvolatile memory; and
a voltage generation circuit configured to apply a voltage to the first nonvolatile memory, the voltage generation circuit comprising a charge pump and an oscillator configured to generate a clock to be used to operate the charge pump,
wherein the voltage generation circuit changes a frequency of the clock.

2. The device of claim 1, further comprising a detection circuit configured to monitor an external power supply voltage and to detect that the power supply voltage has fallen below a predetermined level,
wherein the voltage generation circuit lowers the frequency of the clock when the power supply voltage has fallen below the predetermined level.

3. The device of claim 2, further comprising a state machine configured to execute a rewrite operation in the nonvolatile memory, and to delay state transition of the rewrite operation by the same amount as an increase in a charge time of the charge pump when the power supply voltage has fallen below the predetermined level.

4. The device of claim 2, further comprising a state machine configured to execute a rewrite operation in the nonvolatile memory, to interrupt the rewrite operation when the power supply voltage has fallen below the predetermined level, and to execute the rewrite operation again when the power supply voltage has risen to not less than the predetermined level.

5. The device of claim 2, wherein
the oscillator generates a first clock having a first frequency, and
the voltage generation circuit comprises a frequency divider configured to frequency-divide the first clock to generate a second clock having a second frequency lower than the first frequency.

6. The device of claim 5, wherein the voltage generation circuit comprises a switch configured to select one of the first clock and the second clock.

7. The device of claim 1, wherein the detection circuit comprises:
a voltage divider configured to divide the power supply voltage; and
a comparator having a threshold voltage and configured to compare the threshold voltage with the divided voltage.

8. The device of claim 7, wherein
the comparator comprises a MOSFET,
the MOSFET comprising a source to receive the power supply voltage, a gate to receive the divided voltage, and a drain to output a comparison result.

9. The device of claim 2, wherein
the first nonvolatile memory comprises a flash memory, and
the voltage generation circuit comprises a positive charge pump configured to generate a positive voltage for write, and a negative charge pump configured to generate a negative voltage for erase.

10. The device of claim 1, further comprising:
a second nonvolatile memory; and
a state machine configured to execute a rewrite operation and a read operation in the first and second nonvolatile memories,
wherein the voltage generation circuit apply voltages to the first and second nonvolatile memories, and
the state machine lowers the frequency of the clock upon receiving a read command for the second nonvolatile memory during execution of the rewrite operation in the first nonvolatile memory.

11. The device of claim 10, wherein the state machine delays state transition of the rewrite operation by the same amount as an increase in a charge time of the charge pump when lowering the frequency of the clock.

12. The device of claim 10, wherein
the oscillator generates a first clock having a first frequency, and
the voltage generation circuit comprises a frequency divider configured to frequency-divide the first clock to generate a second clock having a second frequency lower than the first frequency.

13. The device of claim 12, wherein the voltage generation circuit comprises a switch configured to select one of the first clock and the second clock.

14. The device of claim 10, wherein
each of the first and second nonvolatile memories comprises a flash memory, and
the voltage generation circuit comprises a positive charge pump configured to generate a positive voltage for write, and a negative charge pump configured to generate a negative voltage for erase.

15. An IC card comprising:
a nonvolatile semiconductor memory device of claim 1;
a terminal group connectable to an external; and
an interface connected between the nonvolatile semiconductor memory and the terminal group.

16. The card of claim 15, wherein a usable peak current is prescribed.

17. A portable apparatus connected to an IC card of claim 15 via a terminal group,
wherein the IC card stores identification information.
